(19) United States
(12) Patent Application Publication
(10) Pub. No.: US 2025/0343161 A1
(43) Pub. Date: Nov. 6, 2025

(54) Warpage mitigation in a cluster of multiple high bandwidth memory stacks

(71) Applicant: Marvell Asia Pte Ltd, Singapore (SG)

(72) Inventors: Tushar Chauhan, Fremont, CA (US); Dwayne R. Shirley, Valley Glen, CA (US); Richard S. Graf, Gray, ME (US); Wolfgang Sauter, Starksboro, VT (US)

(21) Appl. No.: 19/192,414

(22) Filed: Apr. 29, 2025

Related U.S. Application Data
(60) Provisional application No. 63/641,150, filed on May 1, 2024.

(51) Int. Cl. H01L 23/00; H01L 25/00; H01L 25/065; H10B 80/00

(52) U.S. Cl. CPC H01L 23/562; H01L 25/0657; H01L 25/50; H10B 80/00; H01L 2225/06586

(57) ABSTRACT

An electronic device includes (i) a substrate, (ii) first and second stacks of integrated circuit (IC) dies, the first and second stacks being positioned adjacent to one another over the substrate and having first and second surfaces facing one another, (iii) a first plate disposed between the substrate and the first surface of the first and second stacks, and (iv) a second plate disposed over the second surface of the first and second stacks, each of the first and second plates mechanically connects the first stack to the second stack, overlaps at least a portion of a combined footprint of the first and second stacks and configured to mitigate a warpage in at least one of the first and second stacks.

### CROSS-REFERENCE TO RELATED APPLICATIONS

This application claims the benefit of U.S. Provisional Patent Application 63/641,150, filed May 1, 2024, whose disclosure is incorporated herein by reference.

### FIELD OF THE DISCLOSURE

The present invention relates generally to electronic devices, and particularly to techniques for mitigating warpage in a cluster of multiple high bandwidth memory (HBM) stacks.

### BACKGROUND

High Bandwidth Memory (HBM) devices, which stack multiple integrated circuit (IC) dies, such as Dynamic Random-Access Memory (DRAM) dies, to achieve high-density memory configurations, are prone to warpage due to thermal expansion mismatches between different materials used in their construction. This warpage can lead to challenges in the assembly and reliability of the HBM devices, particularly when integrating HBM devices with other components on a substrate or interposer. As the demand for higher memory bandwidth and capacity in applications such as high-performance computing (HPC) and artificial intelligence (AI) applications continues to grow, addressing the warpage issue in multi-stack HBM devices becomes increasingly relevant for ensuring successful integration and long-term performance of these advanced memory solutions.

The description above is presented as a general overview of related art in this field and should not be construed as an admission that any of the information it contains constitutes prior art against the present patent application.

### SUMMARY

An embodiment of the present invention that is described herein provides an electronic device including: (i) a substrate, (ii) first and second stacks of integrated circuit (IC) dies, the first and second stacks being positioned adjacent to one another over the substrate and having first and second surfaces facing one another, (iii) a first plate disposed between the substrate and the first surface of the first and second stacks, and (iv) a second plate disposed over the second surface of the first and second stacks, each of the first and second plates mechanically connects the first stack to the second stack, overlaps at least a portion of a combined footprint of the first and second stacks and configured to mitigate a warpage in at least one of the first and second stacks.

In some embodiments, the electronic device further includes an encapsulation layer disposed between the first and second stacks. In other embodiments, the encapsulation layer and surrounds the first and second stacks. In yet other embodiments, at least one of the first and second plates overlaps the combined footprint of the first and second stacks and the encapsulation layer.

In some embodiments, at least one of the first and second plates overlaps the combined footprint of the first and second stacks and the encapsulation layer disposed between the first and second stacks. In other embodiments, the first and second stacks are arranged along a first axis and the electronic device further includes at least a vertical plate: (i) arranged along a second axis relative to at least one of the first and second stacks, (ii) having a plane perpendicular to the first and second surfaces, and (iii) configured to mitigate at least a portion of the warpage.

In some embodiments, the first and second stacks are arranged along a first axis and the electronic device further includes at least a vertical plate: (i) arranged along a second axis relative to at least one of the first and second stacks, (ii) having a plane perpendicular to the first and second surfaces, and (iii) configured to mitigate at least a portion of the warpage. In other embodiments, the first and second stacks have first and second sides facing one another along the second axis, and the at least a vertical plate includes a first vertical plate facing the first side, and a second vertical plate facing the second side. In yet other embodiments, the at least a vertical plate has a first coefficient of thermal expansion (CTE) and at least one of the IC dies has a second CTE larger than the first CTE.

In some embodiments, the encapsulation layer is (a) disposed between (i) the first and second stacks, and (ii) the at least a vertical plate, and (b) surrounds the at least a vertical plate. In other embodiments, the electronic device further includes a nonconductive film (NCF) disposed between the at least a vertical plate and at least one of the first and second plates. In yet other embodiments, the first and second stacks of IC dies include first and second stacks of data storage IC dies, respectively, arranged in a dual High Bandwidth Memory (HBM) configuration.

There is additionally provided, in accordance with an embodiment of the present invention, a method for fabricating an electronic device, the method includes (a) disposing an array of terminals on a substrate, and a first plate over the array of terminals, (b) positioning first and second stacks of integrated circuit (IC) dies adjacent to one another over the first plate, the first and second stacks having a first surface facing the first plate, and a second surface facing the first surface, and (c) disposing a second plate over the second surface of the first and second stacks, each of the first and second plates mechanically connects the first stack to the second stack, overlaps at least a portion of a combined footprint of the first and second stacks and is configured to mitigate a warpage in at least one of the first and second stacks.

The present disclosure will be more fully understood from the following detailed description of the embodiments thereof, taken together with the drawings in which:

### BRIEF DESCRIPTION OF THE DRAWINGS

FIG. 1 is a top view of an electronic device incorporating a cluster of multiple high bandwidth memory (HBM) stacks, in accordance with an embodiment that is described herein;

FIG. 2 is a top view of a pair of HBM stacks of the electronic device of FIG. 1, in accordance with an embodiment that is described herein;

FIG. 3 is a sectional view of the pair of HBM stacks of FIG. 2, in accordance with an embodiment that is described herein;

FIG. 4 is a top view of a pair of HBM stacks of the electronic device of FIG. 1, in accordance with another embodiment that is described herein;

FIG. 5 is a sectional view of the pair of HBM stacks of FIG. 4, in accordance with another embodiment that is described herein;

FIG. 6 is a top view of a pair of HBM stacks of the electronic device of FIG. 1, in accordance with an alternative embodiment that is described herein;

FIGS. 7A and 7B are sectional views of the pair of HBM stacks of FIG. 6, in accordance with other embodiments that are described herein;

FIG. 8 is a top view of another pair of HBM stacks of the electronic device of FIG. 1, in accordance with another embodiment that is described herein; and

FIG. 9 is a flow chart that schematically illustrates a method for fabricating the pair of HBM stacks shown in FIGS. 2 and 3, in accordance with an embodiment that is described herein.

### DETAILED DESCRIPTION OF EMBODIMENTS

Embodiments of the present disclosure that are described herein provide techniques for mitigating warpage in a cluster of multiple (e.g., dual) high bandwidth memory (HBM) devices, also referred to herein as HBM stacks. Each HBM stack comprises a stack of integrated circuit (IC) dies, such as Dynamic Random-Access Memory (DRAM) dies configured to store data.

In some embodiments, an electronic device comprises a substrate, such as but not limited to a package substrate or an interposer having electrical connections such as Through-Silicon Vias (TSVs) and electrical traces configured to conduct electrical signals, electrical power and ground, as will be described below. The electronic device further comprises multiple IC dies mounted on the surface of the substrate. In the present example, the electronic device comprises (i) one or more application-specific integrated circuit (ASIC) dies configured to perform computing operations, such as data processing and communication of data signals with other IC dies, and (ii) multiple HBMs associated with each ASIC and configured to exchange data signals with the ASIC over the electrical connections of the substrate.

In some embodiments, at least two HBM stacks, referred to herein as first and second HBM stacks, are positioned over the substrate adjacent to one another (e.g., spaced apart by a gap between about 0.3 mm and 0.5 mm, or any gap less than about 0.8 mm). The electronic device further comprises an encapsulation layer, such as epoxy molded compound (EMC) disposed in the gap (between the first and second HBM stacks) and surrounding the first and second HBM stacks. The pair of HBM stacks has a first outer surface facing the substrate and a second outer surface opposite the first outer surface. In the context of the present disclosure and in the claims the terms “opposite,” “facing,” and grammatical variations thereof are used interchangeably. In some embodiments, (i) a buffer die, also referred to herein as a first plate, is disposed between the substrate and the first surface of the HBMs, and (ii) an array of terminals, such as micro-pillars or balls of a ball grid array, is disposed between the buffer die and the substrate.

In some embodiments, the electronic device comprises a top die, also referred to herein as a second plate, disposed over the second outer surface of the first and second HBM stacks. It is noted that the second plate can be any type of plate, not just a top die. In some embodiments, each of the first and second plates overlaps the combined footprint of the first and second stacks and the filled gap therebetween and mechanically connects the first HBM stack to the second stack. In such embodiments, by mechanically connecting between the HBM stacks, and overlapping the footprint (or at least a portion of the footprint) of the HBM stacks, each of the first and second plates is configured to mitigate warpage in one or both of the first and second HBM stacks.

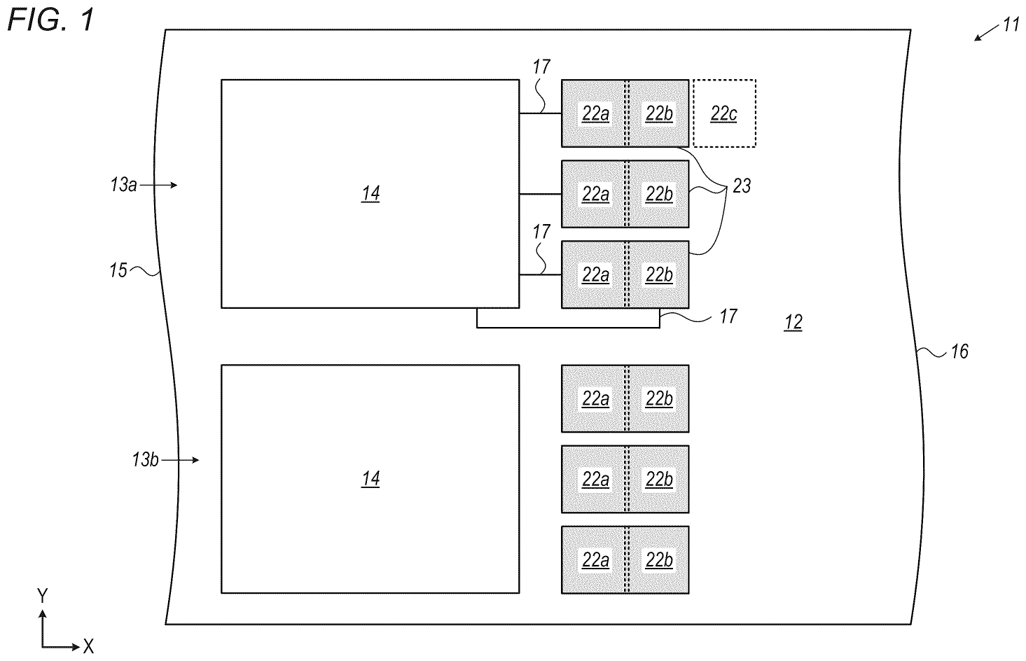

In some embodiments, the DRAM dies of the HBM stack typically comprise a single-crystal silicon substrate, and the electronic device may comprise vertical plates made from silicon, diamond, a nickel-iron alloy, such as an alloy 42 containing approximately 42% nickel and 58% iron, aluminum nitride, silicon nitride or other suitable materials with a coefficient of thermal expansion (CTE) similar to or less than 6 ppm/° C. at about 25° C. For example, the CTE of the single-crystal silicon substrate is about 3 ppm/C at about 25° C. In some embodiments, the HBM stacks are arranged along a first axis with the vertical plates disposed at the sides of the HBM stacks and arranged along a second axis, typically perpendicular to the first axis. Several configurations incorporating at least the embodiments described above and variations thereof are described in detail in FIGS. 1-8 below.

The description above is presented as a general overview of embodiments of the present disclosure, which are described in detail herein.

FIG. 1 is a schematic pictorial illustration of an electronic device 11, in accordance with an embodiment that is described herein.

In some embodiments, electronic device 11 (also referred to herein as a device 11, for brevity) comprises a substrate 12, such as a package substrate or an interposer with electrical 17 connections such as Through-Silicon Vias (TSVs) and electrical traces. Electronic device 11 comprises two modules 13a and 13b, each comprising (i) an application-specific integrated circuit (ASIC) die, referred to as ASIC 14, disposed between sides 15 and 16 of substrate 12, (ii) multiple High Bandwidth Memory (HBM) stacks referred to herein as HBMs 22a, 22b and 22c, and electrical connections 17 configured to conduct electrical signals between ASIC 14 and HBMs 22a-22c. Moreover, electrical connections 17 are further configured to conduct electrical power and electrical ground between (i) substrate 12 and (ii) at least one of HBMs 22a, HBMs 22b and ASICs 14.

In some embodiments, each of modules 13a and 13b comprises three pairs of HBMs 22a and 22b (also referred to as dual HBM) disposed on substrate 12 between ASIC 14 and side 16 of substrate 12. In other embodiments, at least one of modules 13a and 13b may comprise a cluster of three or more HBMs 22, for example, the uppermost cluster of module 13a may comprise HBMs 22a, 22b, and 22c. Additionally, or alternatively, at least one of the clusters of HBMs 22 may be positioned between ASIC 14 and side 15 of substrate 12. In some embodiments, an upper plate 23 (also referred to herein as a plate 23, for brevity), typically made from single-crystal silicon, is positioned over HBMs 22a and 22b and provides a mechanical connection between HBMs 22a and 22b.

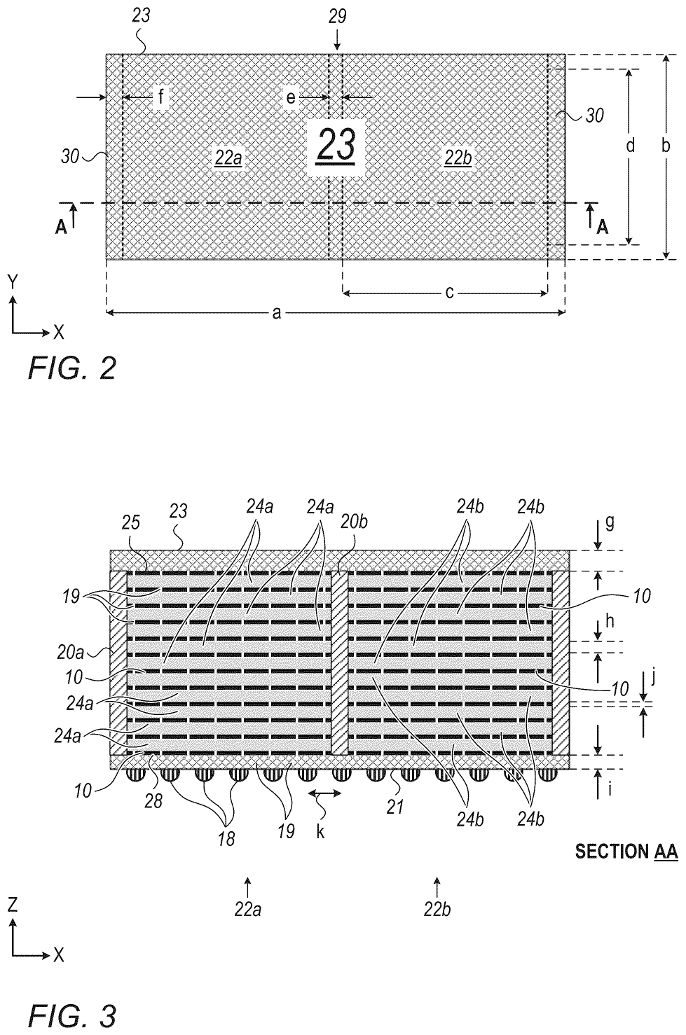

FIG. 2 is a top view of a pair of HBM 22a and 22b of electronic device 11, in accordance with an embodiment that is described herein. It is noted that substrate 12 shown in FIG. 1 above has been removed from the configurations shown in FIGS. 2-7 for the sake of presentation and conceptual clarity, but as described in FIG. 1 above, ASICs 14 and HBMs 22 are mounted on substrate 12, which is configured to exchange the signals between ASICs 14 and HBMs 22.

In some embodiments, HBMs 22a and 22b are arranged along the X-axis of substrate 12 and are covered by upper plate 23 overlapping the combined footprint of (i) HBMs 22a and 22b, (ii) a gap 29 between HBMs 22a and 22b, and (iii) one or more sealing channels 30 typically arranged in a ring surrounding HBMs 22a and 22b.

In the context of the present disclosure, the term “width” refers to the X-axis, the term “length” refers to the Y-axis, and the term “thickness” refers to the Z-axis shown in the sectional views below. In the present example, plate 23 has an overall width “a” (e.g., between about 17.3 mm and 28.3 mm) and a length “b” (e.g., between about 10 mm and 16 mm). Gap 29 has a width “e” (e.g., between about 0.3 mm and 0.5 mm), channels 30 have a width “f” (e.g., between about 0.5 mm and 0.9 mm) at the edge, and HBMs 22a and 22b have a similar width “c” (e.g., between about 8 mm and 13 mm) and a length “d” (e.g., between about 9 mm and 14 mm). It is noted that the dashed lines indicate that plate 23 overlaps all other components that are not visible in the present top view.

FIG. 3 is a sectional view AA of HBMs 22a and 22b shown in FIG. 2, in accordance with an embodiment that is described herein.

In some embodiments, electronic device 11 comprises HBMs 22a and 22b, each comprising multiple IC dies, such as but not limited to data storage IC dies, arranged in vertical stacks along the Z-axis. In the present example, HBM 22a comprises twelve DRAM dies 24a and HBM 22b comprises twelve DRAM dies 24b. Thus, the number and type of stacked IC dies are similar in HBMs 22a and 22b. In other embodiments, at least one of HBMs 22a and 22b may have (i) a different number of IC dies (e.g., between about four and thirty-two DRAM dies), (ii) a different type of IC dies (e.g., non-volatile memory (NVM) dies such as NAND (Not AND) Flash), (iii) a mixed type of IC dies (e.g., a processor disposed at the lowest level and stacked DRAM and/or NVMs stacked over the processor) or (iv) a different number and/or type of IC dies in HBMs 22a and 22b or any other suitable variation.

In some embodiments, the DRAM dies 24a and 24b are stacked using any suitable stacking technology, such as (i) TSVs formed through the substrate of DRAM dies 24a and 24b, and (ii) micro-bumps and a nonconductive film (NCF) 10 of filling material surrounding the micro-bumps that are disposed between each pair of DRAM dies 24a in HBM 22a and each pair of DRAM dies 24b in HBM 22b. In the context of the present disclosure and in the claims, the term electrical connections 19 refers to the TSVs, micro-bumps, and electrical traces formed within the substrate of DRAM dies 24a and 24b and over the surface of DRAM dies 24a and 24b. In such embodiments, HBMs 22a and 22b have a common lower surface 28 and a common upper surface 25, also referred to herein as surfaces 28 and 25, respectively.

In some embodiments, electronic device 11 comprises (i) a buffer die, referred to herein as a plate 21, disposed between substrate 12 (shown in FIG. 1 above) and surface 28 of HBMs 22a and 22b, and (ii) a top die, referred to herein as a plate 23 coupled to surface 25. In some embodiments, each of plates 21 and 23 mechanically connects HBMs 22a and 22b to one another. In other words, both plates 21 and 23 mechanically connect the stacks HBMs 22a and 22b. In the present example, plates 21 and 23 are coupled to HBMs 22a and 22b using the NCF 10 of the filling material surrounding the micro bumps between any pair of the DRAM dies in the HBMs (e.g., a pair of DRAM dies 24a in HBM 22a, and a pair of DRAM dies 24b in HBM 22b). Moreover, plates 21 and 23 overlap at least a portion of the combined footprint of HBMs 22a and 22b and plates 21 and 23. In such embodiments, by overlapping at least a portion of (and typically the entire) the footprint of HBMs 22a and 22b, and mechanically connecting HBMs 22a and 22b, plates 21 and 23 are configured to mitigate warpage in at least one of HBMs 22a and 22b.

In some embodiments, plates 21 and 23 may be made from silicon, diamond, alloy 42 (described above) or any other suitable nickel-iron alloy, aluminum nitride, silicon nitride or other suitable materials with a coefficient of thermal expansion (CTE) similar to or less than 6 ppm/° C. at about 25° C. For example, plates 21 and 23 could be made from single-crystal silicon, which is typically similar to the substrate material of the stacked DRAM dies 24a and 24b (or other sorts of IC dies described above). It is noted the single-crystal as silicon is selected for plates 21 and 23 to match the coefficient of thermal expansion (CTE) (e.g., about 3 ppm/° C. at about 25° C.), and thereby, to reduce mechanical stress and warpage at a range of the specified temperatures (e.g., between about 25° C. and 260° C.) of HBMs 22a and 22b.

In the present example, plate 21 has a thickness “i” (e.g., between about 25 μm and 45 μm) and plate 23 has a larger thickness “g” (e.g., between about 120 μm and 200 μm). In other embodiments, plates 21 and 23 may have any other suitable thickness, different from one another (as described above) or similar to one another. In some embodiments, plate 21 has electrical connections 19, and electronic device 11 further comprises an array of terminals 18, such as micro-pillars (or pins or balls) having a pitch “k” (e.g., between about 8 μm and 60 μm). Terminals 18 and electrical connections 19 are configured to exchange electrical signals and/or electrical power and ground between (i) HBMs 22a and 22b and (ii) substrate 12 (shown in FIG. 1 above).

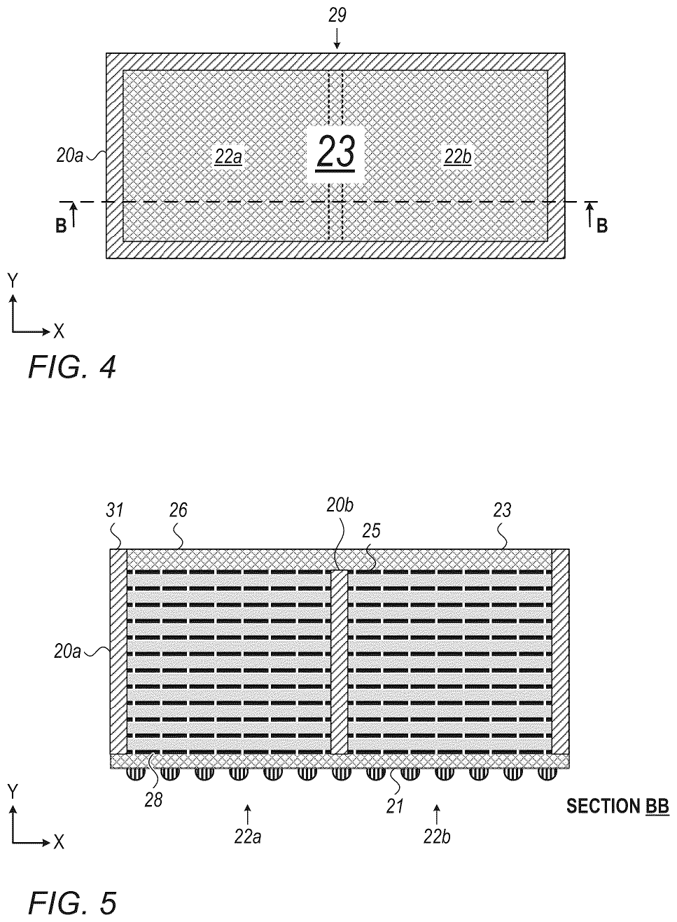

In some embodiments, electronic device 11 comprises an encapsulation layer 20a disposed in sealing channels 30 (shown in FIG. 2 above) at least partially surrounding HBMs 22a and 22b, and an encapsulation layer 20b disposed to fill gap 29 (shown in FIG. 2 above) between HBMs 22a and 22b. In the present example, each DRAM die has a thickness “h” (e.g., between about 27 μm and 47 μm), and the micro-bumps and NCF 10 of the filling material (disposed between each pair of the stacked DRAM dies) have a thickness “j” (e.g., between about 4 μm and 14 μm). Please note that unless specified otherwise, the dimensions described for the structures in FIGS. 2 and 3 also apply to the corresponding structures shown in FIGS. 4, 5, 6, 7A, and 7B below.

In some embodiments, encapsulation layers 20a and 20b are confined between plates 21 and 23, so that in the present example, the upper and lower ends of encapsulation layers 20a and 20b are typically flush with surfaces 25 and 28 of HBMs 22a and 22b.

FIG. 4 is a top view of HBMs 22a and 22b, in accordance with another embodiment that is described herein. In some embodiments, encapsulation layer 20a, which may be disposed in sealing channels 30 (shown in FIG. 2 above), surrounds the entire perimeter of (i) HBMs 22a and 22b and (ii) plate 23. The structure is further described in a BB sectional view shown in FIG. 5 below.

FIG. 5 is a sectional view BB of the pair of HBMs 22a and 22b of FIG. 4, in accordance with another embodiment that is described herein.

In some embodiments, encapsulation layer 20a is disposed over plate 21 so that the lower end of encapsulation layer 20a is typically flush with surfaces 28 of HBMs 22a and 22b. As described in FIG. 4 above, encapsulation layer 20a surrounds the entire perimeter of HBMs 22a and 22b, and plate 23 such that an upper surface 31 of encapsulation layer 20a is approximately flush with an upper surface 26 of plate 23. In some embodiments, the width (along the X-axis) and typically also the length (along the Y-axis, not shown) of plate 21 are larger than that of plate 23, so that plate 21 serves as a base to dispose encapsulation layer 20a.

It is important to note that, as described in FIG. 3 above, encapsulation layer 20b is confined between plates 21 and 23, so that the upper and lower ends of encapsulation layer 20b are typically flush with surfaces 25 and 28 of HBMs 22a and 22b.

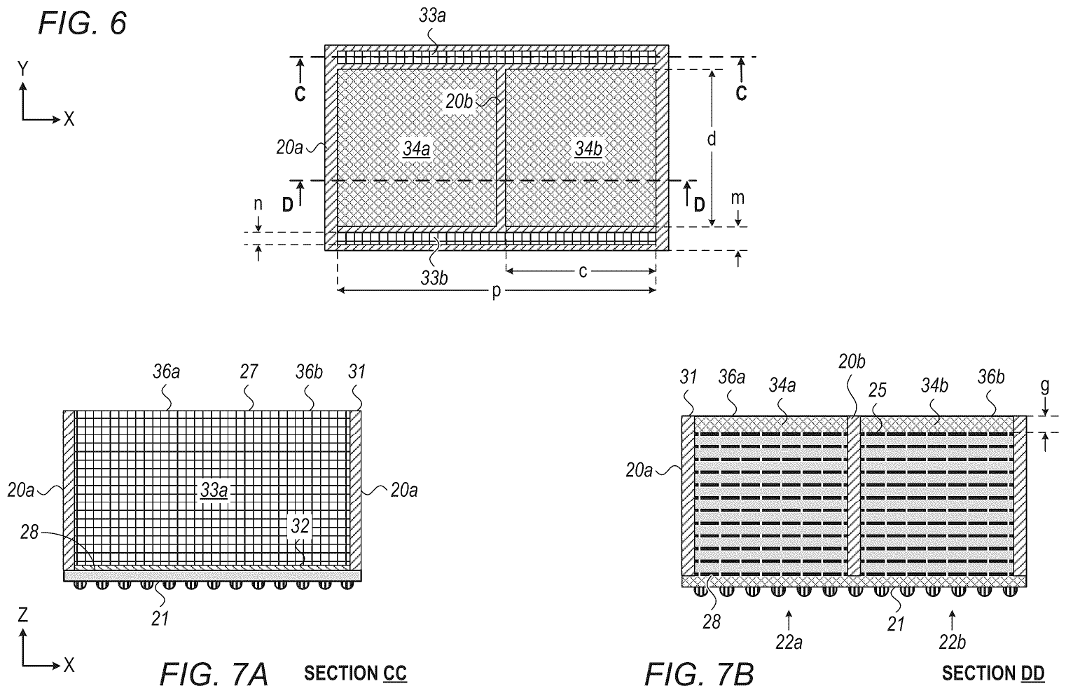

FIG. 6 is a top view of a pair of HBMs 22a and 22b of the electronic device 11, in accordance with an alternative embodiment that is described herein.

In some embodiments, a plate 34a is positioned over HBM 22a, and a separate plate 34b is positioned over HBM 22b. In the present example, plates 34a and 34b have (i) the same width “c” and length “d” of each of HBMs 22a and 22b, and (ii) the same thickness (e.g., thickness “g”) and material of plate 23 (e.g., material having CTE similar to or less than 6 ppm/° C. at about 25° C.), as described in FIG. 3 above. The arrangement of plates 34a and 34b along the X-axis effectively reduces warpage in each of the HBMs 22a and 22b, respectively. However, optimization may be necessary, such as increasing the thickness of plate 21, to further reduce warpage between HBMs 22a and 22b.

In some embodiments, a pair of dummy dies, referred to here as vertical plates 33a and 33b, are positioned at the sides of HBMs 22a and 22b along the Y-axis. This arrangement is designed to further reduce the warpage between HBMs 22a and 22b. In the present example, each of the vertical plates 33a and 33b has a length “p” (e.g., between about 16.3 mm and 26.5 mm), and a width “n” (e.g., between about 0.3 mm and 0.5 mm).

In some embodiments, vertical plates 33a and 33b are made from material(s) having a CTE similar to or less than 6 ppm/° C. at about 25° C., for example silicon, diamond, alloy 42 (described above) or any other suitable nickel-iron alloy, aluminum nitride, silicon nitride, silicon dioxide (SiO₂), or silicon carbide (Sic). In such embodiments, the CTE of the vertical plates 33a and 33b is typically lower than that of the DRAM (or other IC) dies 24a and 24b but could also have a CTE similar to that of dies 24a and 24b, as described above.

Additional embodiments of the structure shown in the top view of FIG. 6 are described in FIG. 7A (a CC sectional view) and FIG. 7B (a DD sectional view).

FIG. 7A is a sectional view CC of the structure comprising the pair of HBMs 22a and 22b of FIG. 6, in accordance with other embodiments that are described herein.

In some embodiments, each of the vertical plates 33a and 33b is surrounded by encapsulation layer 20a so that a combined length “m” of the vertical plate (33a or 33b) and encapsulation layer 20a along the Y-axis is between about 0.6 mm and 0.8 mm.

In some embodiments, the vertical plates 33a and 33b may be disposed over a layer 32 (typically an electrically insulating e. g., layer, made from dielectric materials) deposited over surface 28 of plate 21. In the present example, layer 32 is made from NCF 10 of the filling material disposed between the micro bumps, as described in FIG. 3 above, but in other embodiments, layer 32 may comprise any other suitable material having the same material as NCF 10 but with a different thickness. Alternatively, vertical plates 33a and 33b may be disposed directly over surface 28 of plate 21 (e.g., without layer 32).

In some embodiments, the thickness of vertical plates 33a and 33b (along the Z-axis) is approximately similar to the combined thickness of (i) HBMs 22a and 22b and (ii) plates 34a and 34b. In the present example, the thickness of vertical plates 33a and 33b is generally more than 0.4 mm and typically exceeds 0.7 mm. This thickness is influenced by the thickness of plates 21 and 23 and is primarily determined by the number of DRAM dies 24a and 24b stacked in HBMs 22a and 22b, respectively. In such embodiments, a surface 27 of vertical plates 33a and 33b is approximately flush with (a) surface 31 of encapsulation layer 20a, and (b) surfaces 36a and 36b of plates 34a and 34b, respectively.

FIG. 7B is a sectional view DD of the structure comprising the pair of HBMs 22a and 22b of FIG. 6, in accordance with other embodiments that are described herein. In some embodiments, encapsulation layers 20a and 20b surround plates 34a and 34b (as also shown in the top view of FIG. 6) so that surfaces 31, 36a and 36b are flush with one another as described in FIG. 7A above. Moreover, as shown in sectional view DD, plates 34a and 34b have thickness “g” as described in more detail in FIGS. 3 and 6 above.

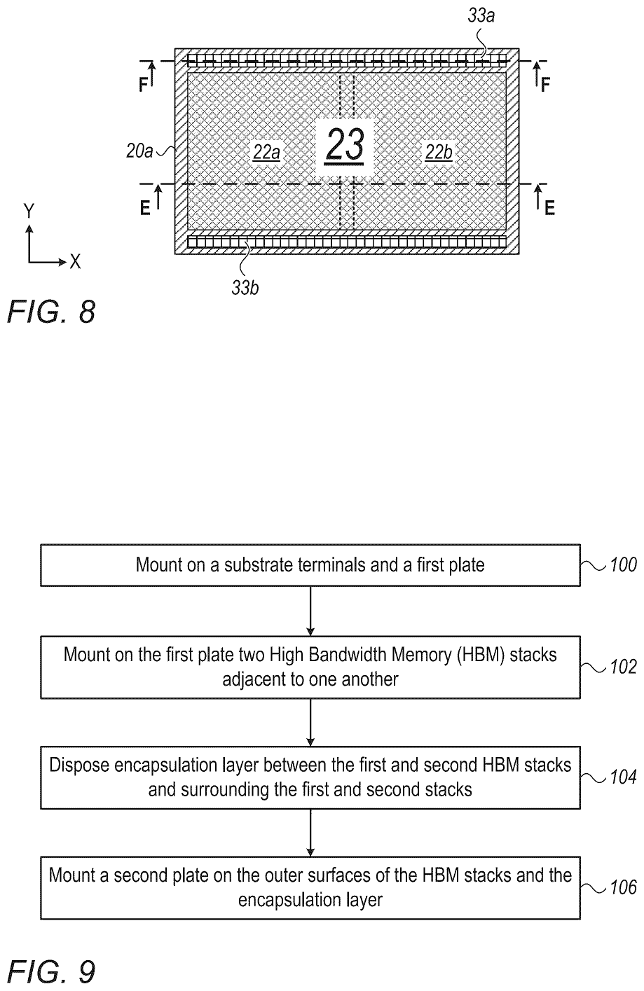

FIG. 8 is a top view of a pair of HBMs 22a and 22b of the electronic device 11, in accordance with another embodiment that is described herein.

In some embodiments, HBMs 22a and 22b are arranged along the X-axis and are covered by plate 23 as described in detail, for example in FIGS. 2 and 4 above. Moreover, vertical plates 33a and 33b are positioned at the sides of HBMs 22a and 22b along the Y-axis, as described in detail in FIG. 6 above.

In some embodiments, a cross section EE of the top view of FIG. 8 has a sectional view similar to that of sectional view CC shown and described in detail in FIG. 7 above. Moreover, a cross section FF of the top view of FIG. 8 has a sectional view similar to that of sectional view BB shown and described in detail in FIG. 5 above. In alternative embodiments, plate 23 may cover HBMs 22a and 22b and encapsulation layers 20a and 20b so that cross section FF of the top view of FIG. 8 may have a sectional view similar to that of sectional view AA shown and described in detail in FIG. 3 above.

In some embodiments, a combination of (i) plates 21 and 23, arranged relative to HBMs 22a and 22b along the Z-axis, and (ii) vertical plates 33a and 33b, arranged relative to HBMs 22a and 22b along the Y-axis, is configured to reduce warpage in the dual HBM structure of HBMS 22a and 22b. Furthermore, the techniques described in FIG. 8 can be adapted for use with a triple HBM structure, such as the module 13a structure (comprising a cluster of HBMs 22a, 22b, and 22c) shown in FIG. 1 above, as well as other multi-stack HBM structures having more than three HBMs.

FIG. 9 is a flow chart that schematically illustrates a method for fabricating electronic device 11, in accordance with an embodiment that is described herein. The method begins at a first mounting step 100 with mounting on substrate 12 (shown in FIG. 1 above) plate 21 and terminals 18, as described in detail in FIG. 3 above. In the present example, substrate 12 already has electrical connections 17 described in detail in FIG. 1 above, and ASICs 14 may be mounted on substrate 12 either before step 100 or after concluding the step of the method that will be described below. In other embodiments, the fabrication method may include the fabrication of substrate 12 carried out before step 100 using suitable techniques known in the art.

At a second mounting step 102, HBMs 22a and 22b are mounted, adjacent to one another, on plate 21 as described in detail in FIGS. 2 and 3 above. At an encapsulation step 104, encapsulation layers 20a and 20b are disposed to surround HBMs 22a and 22b and in gap 29 between adjacent HBMs 22a and 22b, respectively, as described in detail in FIG. 3 above.

At a third mounting step 106, plate 23 is mounted on surface 25 of HBMs 22a and 22b as well as on encapsulation layers 20a and 20b, as described in detail in FIG. 3 above. In some embodiments, the method is applied to all the clusters of the HBMs 22 (e.g., HBMs 22a, 22b and 22c) shown in FIG. 1 above, and may be concluded by mounting ASICs 14 as described in FIG. 1 above.

In other embodiments, the method may comprise one or more intermediate steps for disposing vertical plates 33a and 33b after step 104, and subsequently, the method may proceed to step 106, as described in FIG. 8 above. In alternative embodiments, the present step 106 is excluded from the method, and one or more steps of mounting plates 34a and 34b over HBMs 22a and 22b, respectively, are carried out before or after disposing vertical plates 33a and 33b, as described above and depicted in FIGS. 6, 7A, and 7B above.

It is noted that the embodiments described above are cited by way of example, and that the present invention is not limited to what has been particularly shown and described hereinabove. Rather, the scope of the present invention comprises both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a substrate;
first and second stacks of integrated circuit (IC) dies, the first and second stacks being positioned adjacent to one another over the substrate and having first and second surfaces facing one another;
a first plate disposed between the substrate and the first surface of the first and second stacks; and
a second plate disposed over the second surface of the first and second stacks, wherein each of the first and second plates mechanically connects the first stack to the second stack, overlaps at least a portion of a combined footprint of the first and second stacks and configured to mitigate a warpage in at least one of the first and second stacks.

2. The electronic device according to claim 1, further comprising an encapsulation layer disposed between the first and second stacks.

3. The electronic device according to claim 2, wherein the encapsulation layer surrounds the first and second stacks.

4. The electronic device according to claim 3, wherein at least one of the first and second plates overlaps the combined footprint of the first and second stacks and the encapsulation layer.

5. The electronic device according to claim 2, wherein at least one of the first and second plates overlaps the combined footprint of the first and second stacks and the encapsulation layer disposed between the first and second stacks.

6. The electronic device according to claim 2, wherein the first and second stacks are arranged along a first axis, further comprising at least a vertical plate: (i) arranged along a second axis relative to at least one of the first and second stacks, (ii) having a plane perpendicular to the first and second surfaces, and (iii) configured to mitigate at least a portion of the warpage.

7. The electronic device according to claim 6, wherein the first and second stacks have first and second sides facing one another along the second axis, and wherein the at least a vertical plate comprises a first vertical plate facing the first side, and a second vertical plate facing the second side.

8. The electronic device according to claim 6, wherein the at least a vertical plate has a first coefficient of thermal expansion (CTE) and at least one of the IC dies has a second CTE larger than the first CTE.

9. The electronic device according to claim 6, wherein the encapsulation layer is (a) disposed between (i) the first and second stacks, and (ii) the at least a vertical plate, and (b) surrounds the at least a vertical plate.

10. The electronic device according to claim 6, further comprising a nonconductive film (NCF) disposed between the at least a vertical plate and at least one of the first and second plates.

11. The electronic device according to claim 1, wherein the first and second stacks of IC dies comprise first and second stacks of data storage IC dies, respectively, arranged in a dual High Bandwidth Memory (HBM) configuration.

12. A method for fabricating an electronic device, the method comprising:
disposing an array of terminals on a substrate, and a first plate over the array of terminals;
positioning first and second stacks of integrated circuit (IC) dies adjacent to one another over the first plate, the first and second stacks having a first surface facing the first plate, and a second surface facing the first surface; and
disposing a second plate over the second surface of the first and second stacks,
wherein each of the first and second plates mechanically connects the first stack to the second stack, overlaps at least a portion of a combined footprint of the first and second stacks and is configured to mitigate a warpage in at least one of the first and second stacks.

13. The method according to claim 12, further comprising:
(i) disposing an encapsulation layer between the first and second stacks.

14. The method according to claim 13, further comprising surrounding the first and second stacks with the encapsulation layer.

15. The method according to claim 13, wherein disposing the first and second plates comprises overlapping, by at least one of the first and second plates, (i) the combined footprint of the first and second stacks, and (ii) the encapsulation layer disposed between the first and second stacks and surrounding the first and second stacks.

16. The method according to claim 13, wherein disposing the first and second plates comprises overlapping, by at least one of the first and second plates, (i) the combined footprint of the first and second stacks, and (ii) the encapsulation layer disposed between the first and second stacks.

17. The method according to claim 13, wherein positioning the first and second stacks comprises arranging the first and second stacks along a first axis, further comprising disposing at least a vertical plate: (i) arranged along a second axis relative to at least one of the first and second stacks, (ii) having a plane perpendicular to the first and second surfaces, and (iii) configured to mitigate at least a portion of the warpage.

18. The method according to claim 17, wherein the first and second stacks have first and second sides facing one another along the second axis and wherein disposing the at least a vertical plate comprises disposing a first vertical plate facing the first side and disposing a second vertical plate facing the second side.

19. The method according to claim 17, further comprising disposing the encapsulation layer (a) between (i) the first and second stacks, and (ii) the at least a vertical plate, and (b) surrounding the at least a vertical plate.

20. The method according to claim 12, wherein positioning the and second first stacks of IC dies comprises positioning first and second stacks of data storage IC dies, respectively, arranged in a dual High Bandwidth Memory (HBM) configuration.
